(19) United States
(12) Patent Application Publication
(10) Pub. No.: US 2012/0104185 A1
(43) Pub. Date: May 3, 2012

(54) PORTABLE COMPUTER HOLDER

(76) Inventor: James J. CARROLL, Philadelphia, PA (US)

(21) Appl. No.: 12/916,092

(22) Filed: Oct. 29, 2010

(51) Int. Cl. H05K 5/02; H05K 5/03

(52) U.S. Cl. 248/27.1; 248/145.6

(57) ABSTRACT

An apparatus and method for ergonomically and securely holding a portable computing device and standing the portable computing device at least partially upright on a flat surface are disclosed. The apparatus and method include a holder base with a front face and a rear face opposite the front face, the holder base being configured to hold a portable computing device at its front face by engaging distal edges of the portable computing device, a dome-shaped grip extending from the rear face of the holder base, the dome-shaped grip having at least one opening for receiving a user's finger, and a flange extending from the dome-shaped grip for supporting the holder base at an angle on a flat surface. The holder base may include a central portion configured to mount flush with a rear face of the portable computing device, a plurality of arms extending from the central portion at different angles, the plurality of arms also being configured to mount flush with the rear face of the portable computing device, and a curved lip at a distal end of each of the plurality of arms, each curved having a grooved portion configured to hold a distal edge of the portable computing device therein.

### BACKGROUND OF THE INVENTION

1. Field of the Invention

The present invention relates to an apparatus and method for holding a portable computing device. In particular, the present invention relates to an apparatus and method for ergonomically and securely holding a portable computing device with one hand and for standing it at least partially upright on a work surface.

2. Description of the Related Art

With the increasingly widespread availability of wireless communication network connectivity, such as via cellular phone data networks (e.g., 3G data networks, 4G data networks, etc.) and wireless internet networks (e.g., wireless fidelity (Wi-Fi) networks, wireless local area networks (WLANs), wide area networks (WANs), etc.), there has been a corresponding increase in the popularity of portable computing devices (e.g., tablet computers, KINDLE brand portable reading devices, IPAD brand portable multimedia devices, etc.). Such portable computing devices are designed to allow users to engage in various computer-related activities (e.g., browsing the internet, reading and sending e-mail, reading and drafting documents, data entry, shopping, etc.) away from a desk or other work surface (e.g., sitting on a couch, sitting on a subway train, standing up, etc.). Accordingly, they are relatively small in size so they can be more easily transported (e.g., in a purse or briefcase) while remaining large enough to provide a dynamic and meaningful user interface (e.g., a large display and a functional keyboard).

Portable computing devices are typically provided in the shape of a flat tablet or notebook. And because users will need at least one hand free to interact with the portable computing device via its user interface, the device will often need to be held only by the other hand. But the requirement that the portable computing device be large enough to provide a dynamic and meaningful user interface often makes gripping such tablet-shaped devices awkward, and even painful—particularly for prolonged periods of use. For example, merely wrapping the fingers of one hand around the peripheral edge of the device while using the other hand to interact with the user interface of the device can result in injuries to the fingers and/or wrist of the gripping hand after prolonged periods of use (e.g., Carpal Tunnel Syndrome). Moreover, when gripping such devices is awkward, users are more prone to drop and damage them. Accordingly, there is a need for an apparatus and method for ergonomically and securely holding a portable computing device with one hand.

In addition, because portable computing devices are typically provided in the shape of a flat tablet or notebook, they will lie flat on a desk or other work surface when placed thereon. That orientation is not ideal for interacting with the device because it does not provide a good angle from which the user can view the display of the user interface. Although stands for holding portable computing devices at a desirable viewing are known, such stands are generally bulky and, therefore, not suited for being carried around with the device (e.g., in a purse or briefcase). Moreover, those stands are not suitable for ergonomically and securely holding the device with one hand. Accordingly, there is a need for an apparatus and method that is not only suited for ergonomically and securely holding a portable computing device with one hand, but that is also suitable for standing it at least partially upright on a work surface.

### SUMMARY OF THE INVENTION

To resolve at least the problems discussed above, it is an object of the present invention to provide an apparatus and method for ergonomically and securely holding a portable computing device and standing the portable computing device at least partially upright on a flat surface. The apparatus and method include a holder base with a front face and a rear face opposite the front face, the holder base being configured to hold a portable computing device at its front face by engaging distal edges of the portable computing device, a dome-shaped grip extending from the rear face of the holder base, the dome-shaped grip having at least one opening for receiving a user's finger, and a flange extending from the dome-shaped grip for supporting the holder base at an angle on a flat surface. And the holder base may include a central portion configured to mount flush with a rear face of the portable computing device, a plurality of arms extending from the central portion at different angles, the plurality of arms also being configured to mount flush with the rear face of the portable computing device, and a curved lip at a distal end of each of the plurality of arms, each curved having a grooved portion configured to hold a distal edge of the portable computing device therein. Those and other objects, advantages, and features of the present invention will become more readily apparent by the following written description, taken in conjunction with the accompanying drawings and claims.

### BRIEF DESCRIPTION OF THE DRAWINGS

Many aspects of the present invention can be better understood with reference to the accompanying drawings, which are part of the specification and represent exemplary embodiments of the present invention. The components in the drawings are not necessarily to scale, emphasis instead being placed upon illustrating the principles of the present invention. And in the drawings, like reference numerals designate corresponding parts throughout the several views.

FIG. 1A is an isometric view illustrating a portable computer holder according to a non-limiting embodiment of the present invention;

FIG. 1B is a sectional view of the portable computer holder illustrated in FIG. 1A taken along line B-B;

FIG. 2A is an isometric view illustrating the holder base of the portable computer holder illustrated in FIG. 1A;

FIG. 2B is a plan view of the holder base illustrated in FIG. 2A;

FIG. 2C is an elevation view of the holder base illustrated in FIG. 2A;

FIG. 3A is an isometric view illustrating the grip flange of the portable computer holder illustrated in FIG. 1A;

FIG. 3B is an elevation view of the grip flange illustrated in FIG. 3A;

FIG. 4A is an isometric view illustrating an example of one of the ergonomic and secure grip positions a user can enjoy with the portable computer holder of FIG. 1A;

FIG. 4B is an isometric view illustrating an example of another one of the ergonomic and secure grip positions a user can enjoy with the portable computer holder of FIG. 1A;

FIG. 5A is an elevation view taken from the side illustrating the portable computer holder of FIG. 1A standing partially upright on a flat surface;

FIG. 5B is an elevation view taken from the rear illustrating the portable computer holder of FIG. 1A standing partially upright on a flat surface;

FIG. 6A is an isometric view illustrating the cover of the portable computer holder illustrated in FIG. 1A;

FIG. 6B is an elevation view of the cover illustrated in FIG. 6A;

FIG. 7A is an isometric view illustrating a belt clip according to a non-limiting embodiment of the present invention;

FIG. 7B is an elevation view of the belt clip illustrated in FIG. 7A;

FIG. 7C is an isometric view illustrating the belt clip of FIG. 7A installed on the portable computer holder illustrated in FIG. 1A; and

FIG. 8 is a plan view of a portable computer holder according to another non-limiting embodiment of the present invention.

### DETAILED DESCRIPTION OF THE PREFERRED EMBODIMENTS

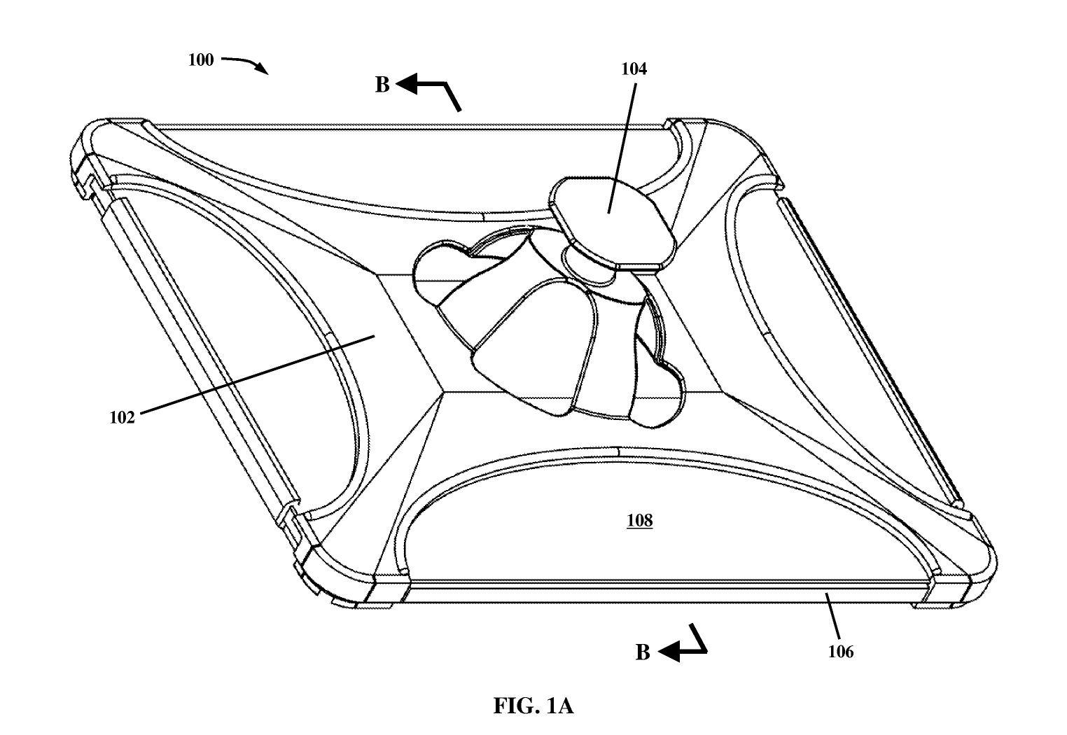

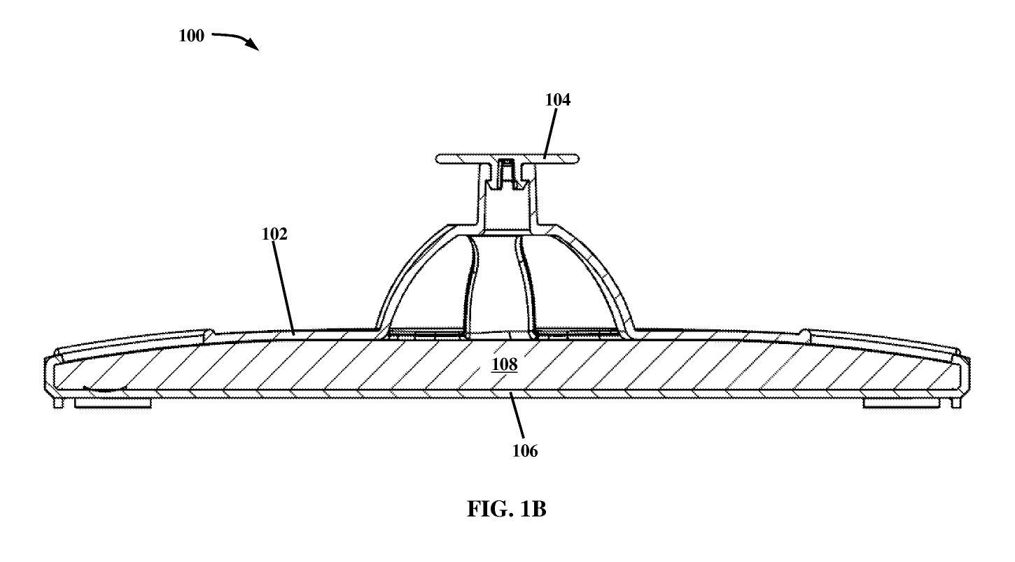

Turning to FIGS. 1A and 1B, the portable computer holder 100 of the present invention includes a holder base 102, a grip flange 104, and a front cover 106. A portable computing device 108 is disposed in the holder base 102 so it can be ergonomically and securely gripped, and a front cover 106 is removable attached to the portable computing device 108 to protect the user interface portion at the front face of the portable computing device 108 from contaminants and scratching when not in use. The front cover 106 is removed from the portable computing device 108 when a user is interacting with the portable computing device 108. The grip flange 104 operates as a counterweight and provides additional grip for a user when holding the holder base 102 and portable computing device 108 in one hand. The flange grip 102 also provides a mechanism for standing the holder base 102 and portable computing device 108 at least partially upright on a work surface. Accordingly, the present invention is suited both for ergonomically and securely holding a portable computing device with one hand and for standing it at least partially upright on a work surface.

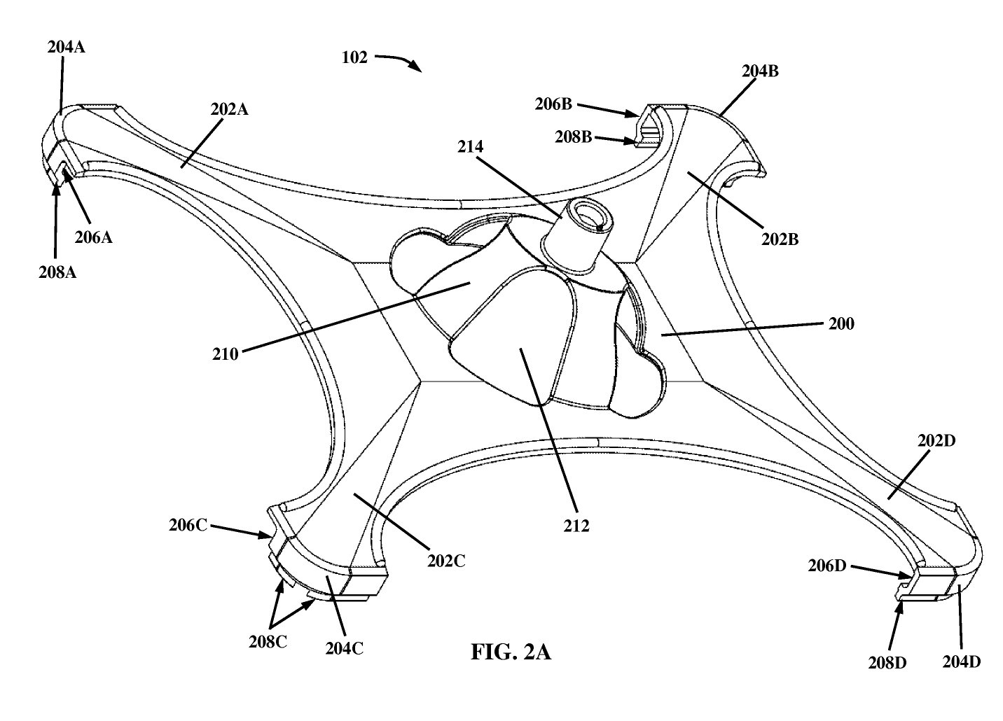

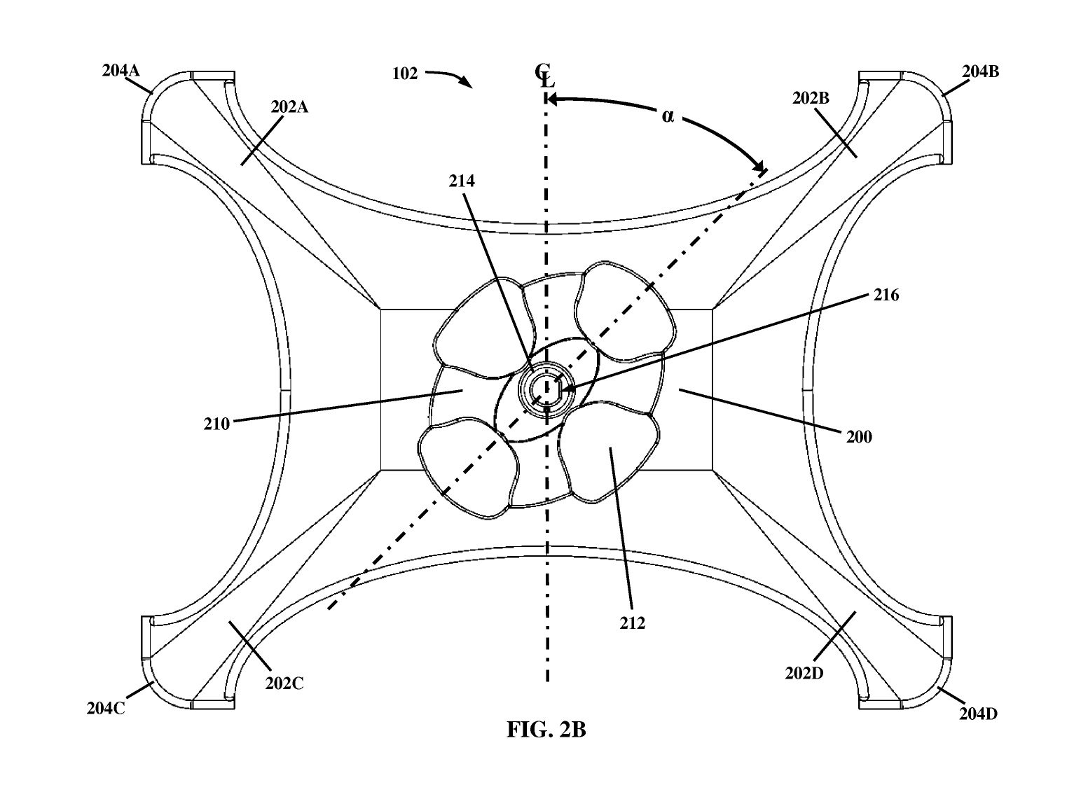

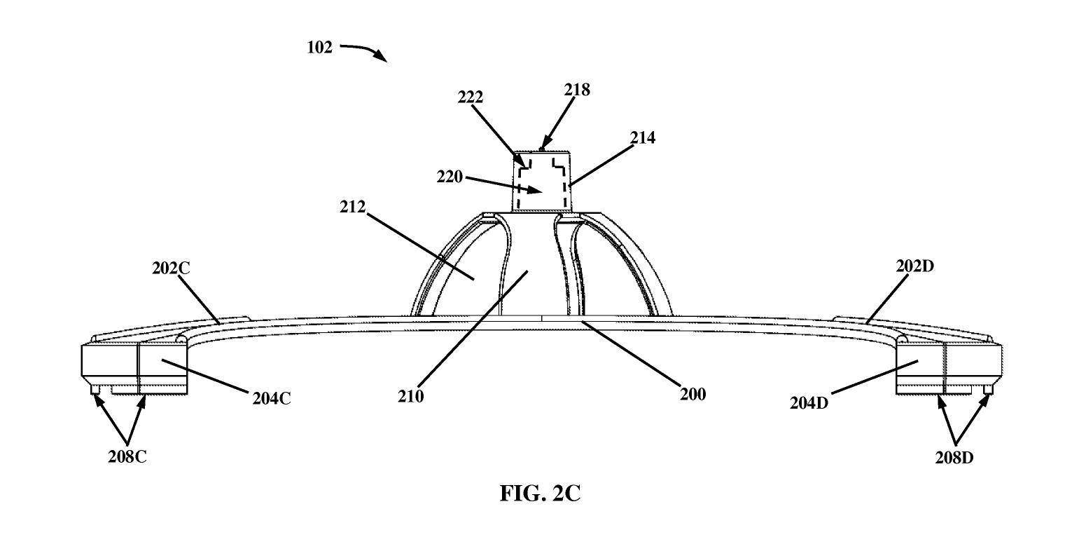

As illustrated in more detail in FIGS. 2A-2C, the holder base 102 includes a central portion 200 from which four arms 202A-202D extend. The central portion 200 provides a substantially flat surface that is configured to mount flush with the rear face of the portable computing device 108. Accordingly, the central portion 200 is substantially parallel to a plane defined by the rear face of the portable computing device 108. The four arms 202A-202D extend from the central portion 200 in substantially the same plane as the central portion 200 in directions corresponding to the four corners of the portable computing device 108.

At the distal end of each of the form arms 202A-202D is a corresponding curved lip 204A-204D configured to wrap around a respective corner of the portable computing device 108. The curved lips 204A-204D are positioned at the four corners of the portable computing device 108 to hold the portable computing device 108 securely in lateral directions (i.e., in directions parallel to the plane defined by the rear face of the portable computing device 108). Each curved lip 204A-204D includes a grooved portion 206A-206D that is formed substantially perpendicular to the central portion 200 of the holder base 102 and, therefore, substantially perpendicular to the plane defined by the rear face of the portable computing device 108. Each grooved portion 206A-206D is approximately the same width as the thickness of the portable computing device 108 so that the respective corners of the portable computing device 108 can be disposed therein. Part of each grooved portion 206A-206D extends over the front face of the portable computing device 108 to hold the portable computing device 108 securely in the vertical direction (i.e., in the direction perpendicular to the plane defined by the rear face of the portable computing device 108).

Preferably, each grooved portion 206A-206D has a width slightly less than the thickness of the portable computing device 108 so as to provide an interference fit between the curved lips 204A-204D and the corners of the portable computing device 108. The holder base 102 is preferably made from a flexible material, such as a thermoplastic elastomer (e.g., santoprene, Alcryn, Estane, Hytrel, Low-density polyethylene (LDPE), etc.), so that one or more of the four arms 202A-202D and/or curved lips 204A-204D can be manipulated (e.g., bent, folded, rotated, etc.) to allow installation of the portable computing device 108 in the holder base 102 between the curved lips 204A-204D and within the grooved portions 206A-206D of the curved lips 204A-204D. The holder base 102 is also preferably made from a flexible material so the central portion 200 and arms 202A-202D can conform to the shape of the rear face of the portable computing device 108 when the rear face of the portable computing device 108 is not perfectly flat. And the holder base 102 is preferably dimensioned to suit the specific size and shape of a particular portable computing device 108 so as to ensure that particular portable computing device 108 is held as securely as possible at its corners by the four curved lips 204A-204D of the holder base 102.

One or more feet 208A-208D are provided on the part of each grooved portion 206A-206D that extends over the front face of the portable computing device 108. Each of the feet 208A-208D extends substantially perpendicular to the front face of the portable computing device 108 at a peripheral edge of a corresponding curved lip 204A-204D. The feet 208A-208D are configured to extend beyond the front face of the portable computing device 108 to protect the front face when the holder base 102 and portable computing device 108 are placed on a flat surface with the front face of the portable computing device 108 facing toward the flat surface (i.e., a face-down position). And the part of each grooved portion 206A-206D that extends over the front face of the portable computing device 108 only extends over the front face of the portable computing device 108 a sufficient amount to secure it in place while leaving the user interface—in particular, the display—of the portable computing device fully accessible to the user. In that way, the curved lips 204A-204D at the corners of the holder base 102 secure the portable computing device 108 and protect its front face while leaving the user interface portion fully accessible to the user.

Extending from the central portion 200 of the holder base 102 is a domed structure 210 with which a user can ergonomically and securely grip the holder base 102 and, therefore, the portable computing device 108 when it is installed therein. As illustrated in FIG. 2B, the domed structure 210 is elliptical in cross section with its major axis and minor axis lying in the same plane as the central portion 200 of the holder base 102. As illustrated in FIG. 2C, the domed structure 210 is in the shape of half an ellipse (e.g., a parabola) in a direction perpendicular to its cross section. And as also illustrated in FIG. 2B, the domed structure 210 is angled with respect to the rectangular shape of the holder base 102 defined by its four corners at feet 208A-208D. Preferably, the major axis of the elliptical shape of the domed structure 210 is at an angle α of about +45° with respect to the centerline (dotted-dashed line), or axis of symmetry, of the holder base 102.

The domed structure 210 is elliptical so that it will easily fit in various hand sizes. For example, users with smaller hands can grip the domed structure 210 around its minor axis so the users' fingers do not need to travel as far from one side of the domed structure to the other and the domed structure will comfortably fill the user's hand. And users with larger hands can grip the domed structure 210 around its major axis so the users' fingers will need to travel far enough from one side of the domed structure 210 to the other that the domed structure 210 comfortably fills the user's hand. By fitting different hands sizes in that way, the elliptical shape of the domed structure 210 helps ensure the user's grip is not only comfortable, but also secure.

The domed structure 210 is positioned at an angle α so it will more naturally fit in a user's hand when the user is holding the portable computer holder 100 and portable computing device 108 at a position in front of his or her body. Accordingly, that angle α corresponds to the angle of a user's arm when the user holds the holder base 102 and portable computing device 108 centrally in front of his or her body. That angle α naturally occurs as the user's arm extends from a position at the user's side to the position centrally in front of his or her body. And that angle α can be reversed (e.g., switched from +45° to −45°) based on which hand the user will utilize to grasp the holder base 102 and portable computing device 108 as well as whether the user prefers to grip the domed structure 210 along its minor axis or its major axis. Or the domed structure 210 can be provided with a circular cross section so that it will fit a user's hand the same way regardless of the direction from which the user grasps it. And when the domed structure 210 is circular in cross section, it can be formed with different diameters to suit different hand sizes.

The domed structure 210 includes a plurality of elongated openings 212 extending from the central portion 200 of the holder base 102 toward the pinnacle of the domed structure 210. A portion of each opening may also extend into the central portion 200 of the holder base 102 in the plane of the holder portion 200. Each opening 212 is configured to receive one or more of a user's fingers therein to further provide an ergonomic and secure gripping surface. Each opening 212 is preferably rounded toward the pinnacle of the domed structure 210 to fit the contour of a finger.

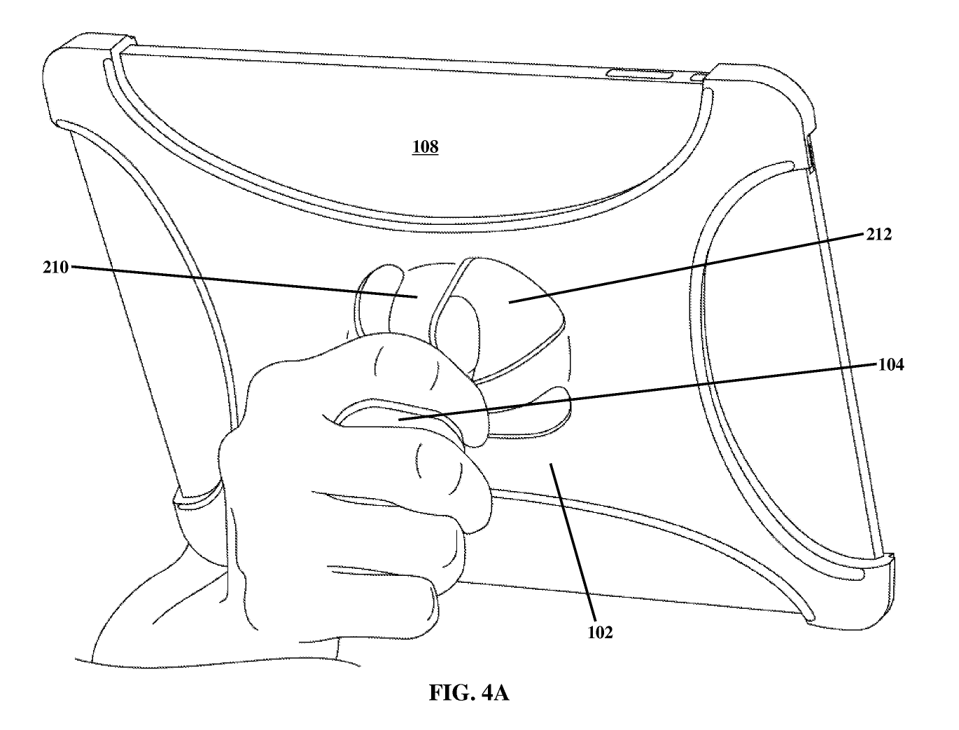

At least one of the openings 212 is placed in line with the angle α of the domed structure 210 so a user can insert one of his or her fingers—preferably the thumb—directly into that opening 212 without the need to rotate his or her hand at the wrist (see, e.g., FIG. 4A). With that opening 212 serving as a starting point, the other openings may be disposed equidistantly from each other around the perimeter of the domed structure 210 in an elliptical array. Preferably, there are four openings 212 spaced 90° apart from each other so that two of the openings 212 are opposite to each other and in line with the angle α of the domed structure 210 and the other two openings are opposite each other and perpendicular to the angle α of the domed structure 210. That configuration allows a user to insert one of his or her fingers directly into an opening 212 in four different orientations without the need to rotate his or her hand at the wrist—right-side-up and up-side-down with the longer edge of the rectangular shape of the holder base 102 parallel to the ground (i.e., right-side-up and up-side-down in the “landscape” orientation) and right-side-up and up-side-down with the longer edge of the rectangular shape of the holder base 102 perpendicular to the ground (i.e., right-side-up and up-side-down in the “portrait” orientation). Moreover, there will be an opening 212 into which a user can directly insert one of his or her fingers without bending his or her wrist in each of those orientations regardless of which hand the user utilizes to grasp the domed structure 210.

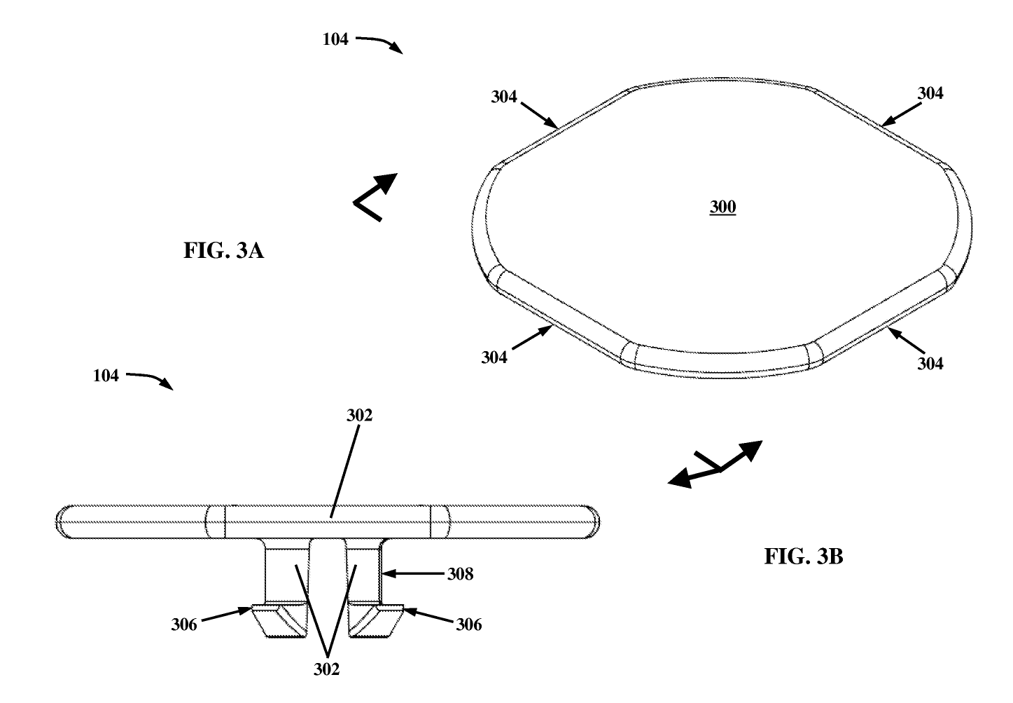

Extending from the pinnacle of the domed structure 210 is an attachment mechanism 214 for attaching the grip flange 104 to the holder base 102. The attachment mechanism 214 extends substantially perpendicular to the central portion 200 of the holder base 102 and includes a flat portion 216 (FIG. 2B) and a cylindrical tab 218 (FIG. 2C) configured to engage a corresponding flat portion 308 (FIG. 3B) and a corresponding cylindrical opening (not shown), respectively, in the grip flange 104. The attachment mechanism 214 includes a hollow bore 220 (FIG. 2C) configured to receive a plurality of attachment mechanisms 302 (FIG. 3B) on the grip flange 104. A cylindrical lip 222 (FIG. 2C) is provided on an inner wall of the bore 220 with a smaller diameter than the diameter of the bore 220 to engage hooked tabs 306 (FIG. 3B) on the attachment mechanisms 302 (FIG. 3B) of the grip flange 104, as illustrated in FIG. 1B. The flat portion 216 and the cylindrical tab 218 operate to prevent the grip flange 104 from rotating on the attachment mechanism 214 when it is attached to the holder base 102, and the cylindrical lip 222 holds the grip flange 104 securely attached to the attachment mechanism 214.

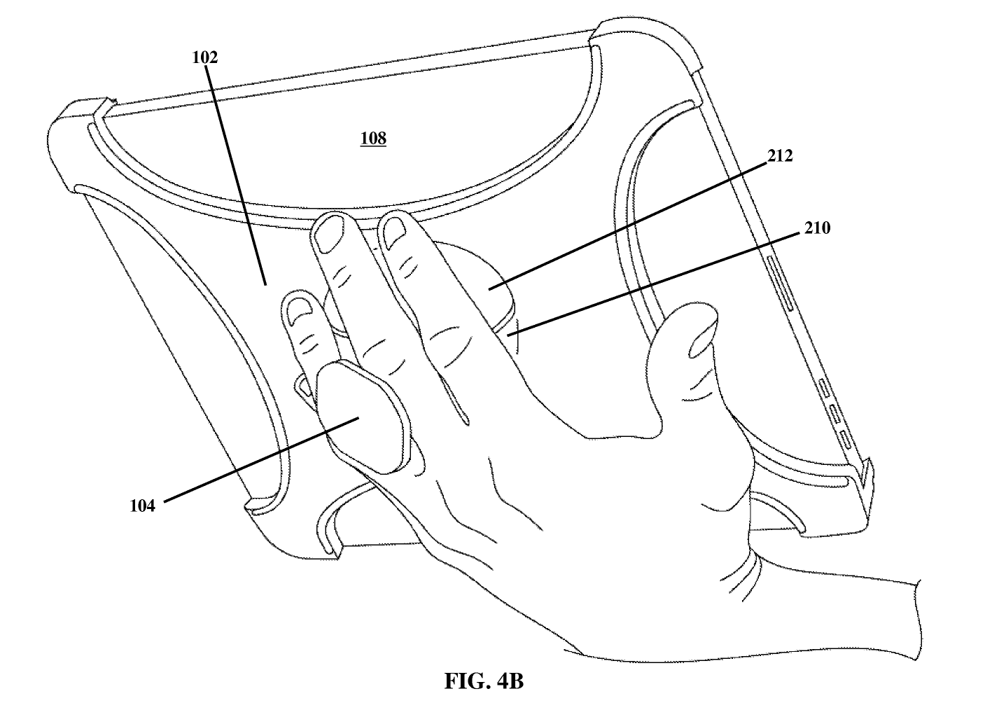

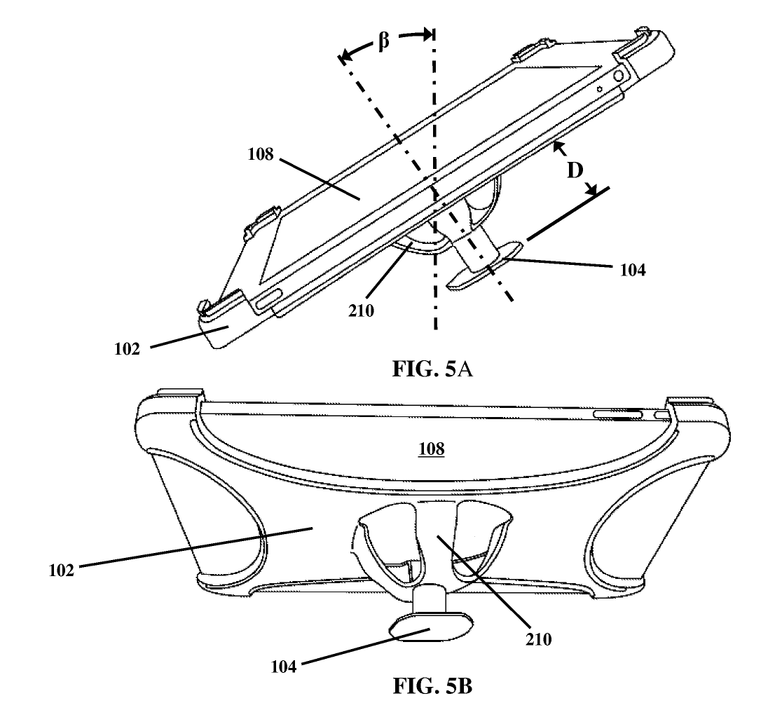

As illustrated in FIG. 3A, the grip flange 104 includes a substantially flat flange base 300. The flange base 300 includes a plurality of flat surfaces 304 at its peripheral edges that are configured to be substantially parallel with the edges of the rectangular shape of the holder base 102 defined by its four corners at feet 208A-208D. Because those flat surfaces 304 are substantially parallel with the edges of the rectangular shape of the holder base 102, they will also be parallel with the edges of a portable computing device 108 being held in the portable computer holder 100. Those flat surfaces 304 will therefore provide additional stability when standing the portable computer holder 100 and portable computing device 108 at least partially upright on a work surface (see, e.g., FIGS. 5A and 5B). Moreover, those flat surfaces will support the portable computer holder 100 and portable computing device 108 in an orientation suitable for interacting with the user interface of the portable computing device 108 (i.e., with the display of the user interface in the landscape or portrait orientation and at a good angle from which the user can view the display). In a like manner, if the portable computing device 108 is some shape other than rectangular, the flat surfaces 304 can be placed in different locations on the grip flange 104 to ensure that the user interface of the portable computing device 108 is in a suitable orientation when standing it at least partially upright on a work surface.

As illustrated in FIG. 3B, the grip flange 104 also includes a plurality of attachment mechanisms 302 extending substantially perpendicular from the flange base 300 at a central location of the flange base 300. The plurality of attachment mechanisms 302 are configured to mate with the attachment mechanism 214 on the domed structure 200 of the holder base 102. Each of those attachment mechanisms 304 includes a hooked tab 306 configured to engage the cylindrical lip 222 (FIG. 2C) in the bore 220 of the attachment mechanism 214 on the domed structure 210. And one of those attachment mechanisms 300 includes a flat portion 308 configured to engage the flat portion 216 (FIG. 2B) of the attachment mechanism 214 on the domed structure 200.

The grip flange 104 also includes a cylindrical opening (not shown) on the same side of the flange base 300 as the attachment mechanisms 302. The cylindrical opening is configured to receive the cylindrical tab 218 (FIG. 2C) of the attachment mechanism 214 on the domed structure 200 when the grip flange 104 is attached to the holder base 102. As discussed above, the cylindrical opening and flat portion 308 on the grip flange 104 operate to prevent the grip flange 104 from rotating on the attachment mechanism 214 when it is attached to the holder base 102, and the hooked tab 306 holds the grip flange 104 securely attached to the attachment mechanism 214. Other mechanisms are also envisioned for attaching the grip flange 104 to the holder base 102 without departing from the spirit and scope of the invention, such as threaded engagement, sonic welding, gluing, and forms of snapped engagement other than that described above. In the alternative, the grip flange 104 can be formed integrally with the holder base 102 from a single piece of material. Regardless of whether the holder base 102 and grip flange 104 are formed as a separate pieces or formed integrally from a single piece of materially, they are preferably formed from the same material formed by injection modling.

The unique configuration of the domed structure 210 and grip flange 104 of the portable computer holder 100 provide multiple grip positions that can be used to ergonomically and securely hold a portable computing device 108 with only one hand, thereby freeing up the other hand to interact with the user interface of the portable computing device 108. As illustrated in FIG. 4A, for example, a user can place his or her thumb through the opening 212 that is in line with the angle α of the domed structure 210 while wrapping his or her other fingers and palm around the outside of the domed structure 210 and grip flange 104 so that the flange base 300 of the grip flange 104 is disposed between two of the user's adjacent fingers—preferably between the user's index finger (digitus secundus manus) and middle finger (digitus tertius). Or as illustrated in FIG. 4B, a user can wrap his or her palm and fingers around the domed structure 210 with his or her thumb facing outward away from the domed structure and the attaching mechanisms 214 and 302 of the grip flange 104 and the domed structure 210 disposed between two of the user's adjacent fingers—preferably between the user's middle finger (digitus tertius) and ring finger (digitus annuláris).

In the grip position illustrated in FIG. 4A, the user's palm is substantially perpendicular to the central portion 200 of the holder base 102 and, therefore, substantially perpendicular to the plane defined by the rear face of the portable computing device 108. And because the flange base 300 of the base portion 104 is disposed between the user's fingers in that grip position, the flange base of the base portion 104 will provide additional leverage for controlling the pitch (i.e., the viewing angle) of the portable computing device 108 with the portable computer holder 100. Also in that grip position, the user's wrist is neutral to 5° and the weight of the portable computer holder 100 and portable computing device 108 are supported by the larger, stronger muscles in the user's hand and wrist. Accordingly, that grip position is five times more efficient (i.e., it consumes less of the user's energy) than holding the portable computing device 108 by wrapping the fingers of one hand around the peripheral edge of the portable computing device 108.

In the grip position illustrated in FIG. 4B, the user's fingers are spread across the central portion 200 of the holder base 102 and the rear face of the portable computing device 108. By spreading the user's fingers across the central portion 200 of the holder base 102 and the rear face of the portable computing device 108, a broader and more stable base is provided for holding the portable computer holder 100 and portable computing device 108. And because the user's hand is disposed between the central portion 200 of the holder base 102 and the flange base 300 of the grip flange 104 in that grip position, the portable computer holder 100 is held securely to the user's hand by the grip flange 104. Also in that position, the portable computer holder 100 and portable computing device 108 are supported by the larger, stronger muscles in the user's arm and elbow. And like the grip position illustrated in FIG. 4A, the grip position illustrated in FIG. 4B is significantly more efficient than holding the portable computing device 108 by wrapping the fingers of one hand around the peripheral edge of the portable computing device 108. Various other grip positions are also possible that provide similar advantages.

In addition to providing extra leverage and a more secure grip, the grip flange 104 operates as a counterweight to help balance the portable computer holder 100 and portable computing device 108 in a user's hand. The grip flange 104 also allows the portable computer holder 100 and portable computing device 108 to be stood at least partially upright on a flat surface, similar to the easel on a picture frame. Accordingly, as illustrated in FIGS. 5A and 5B, the grip flange 104 is configured to extend from the domed structure 210 of the holder base 102 a sufficient distance D to support the portable computer holder 100 at a desirable angle for viewing and interacting with the user interface of the portable computing device 108. And as discussed above, the flat surfaces 304 at the peripheral edges of the flange base 300 provide additional stability for supporting the portable computer holder 100 and portable computing device 108 with the display of the user interface in the landscape or portrait orientation and at a good angle from which the user can view the display.

By requiring the user to use less energy to grip the portable computing device 108, the portable computer holder 100 of the present invention allows a user to grip the portable computing device 108 more comfortably for longer periods of time. Accordingly, the portable computer holder 100 of the present invention reduces the likelihood of injuries to a user's fingers and/or wrist due to prolonged use of a portable computing device 108. The likelihood of injury is further reduced by the portable computer holder 100 of the present invention because the different grip positions allow a user to utilize different muscles to support and stabilize the portable computer holder 100 and portable computing device 108. Thus, a user can switch between many different grip positions if one of those grip positions becomes tiresome and/or uncomfortable. Moreover, by providing a stable and secure grip for holding the portable computing device 108, the portable computer holder 100 of the present invention also greatly reduces the likelihood of dropping and damaging often-expensive portable computer devices 108.

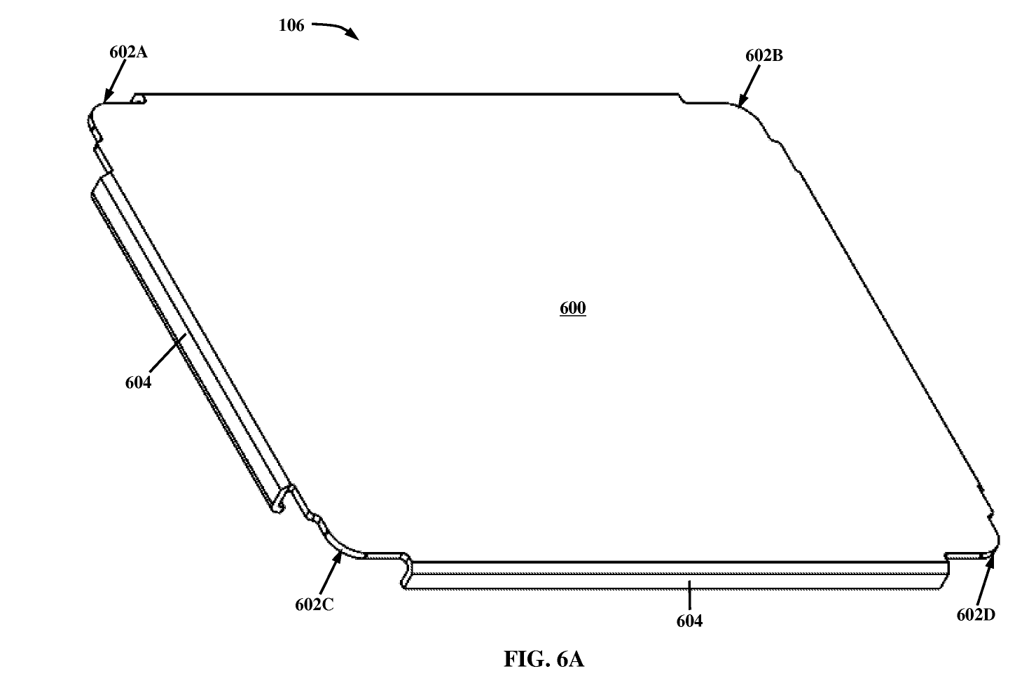

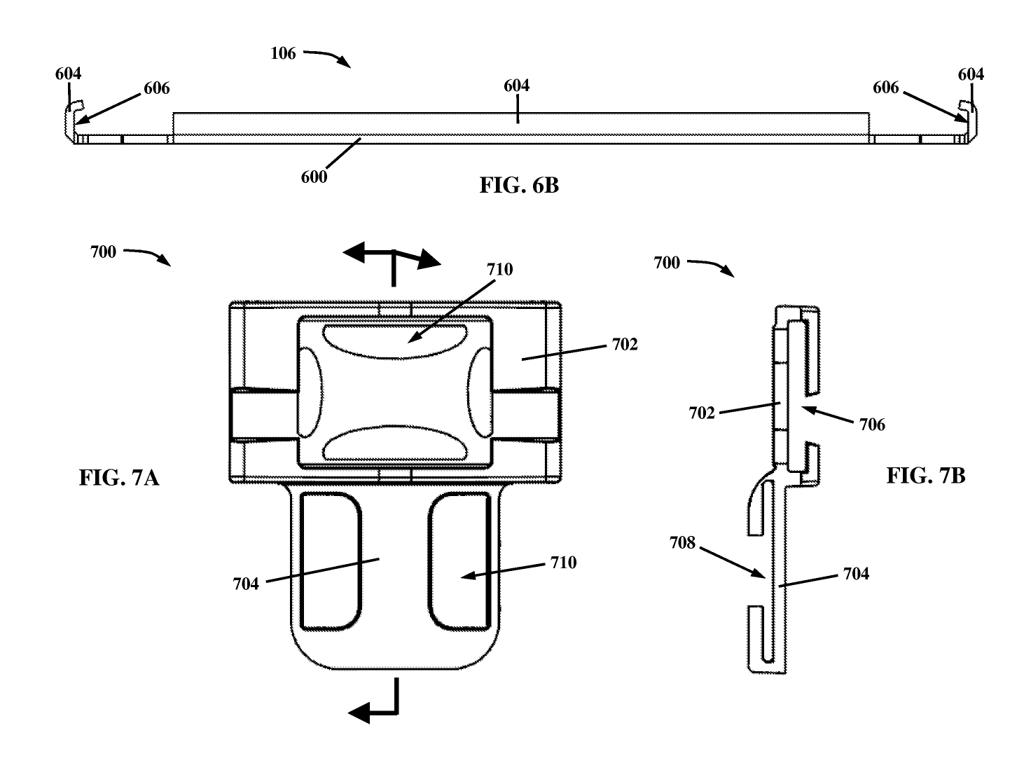

As illustrated in FIGS. 6A and 6B, the cover 106 for the portable computer holder 100 includes a substantially flat main body 600 that is configured to mount flush with and cover the front face of the portable computing device 108. Accordingly, the main body is substantially parallel to a plane defined by the front face of the portable computing device 108 and is substantially the same shape as the front face of the portable computing device 108, except where the curved lips 204A-204D at the corners of the holder base 102 extend over the front face of the portable computing device 108. The main body includes cutout portions 602A-602D at each of its four corners that are configured to receive the curved lips 204A-204D at the corners of the holder base 102 when both the holder base 102 and the cover 106 are installed on the portable computing device 108. Accordingly, the entire front face of the portable computing device 108 will be covered when the portable computing device 108 is installed between the holder base 102 and the cover 106.

The main body 600 of the cover 106 also includes a plurality of curved lips 604 extending substantially perpendicular to the plane in which the main body 600 lies and, therefore, substantially perpendicular to the plane defined by the front face of the portable computing device 108. Each curved lip 604 includes a grooved portion 606 that is formed substantially perpendicular to the main body 600 Like the grooved portions 206A-206D in the curved lips 204A-204D of the holder base 102, each grooved portion 606 in the curved lips 604 of the cover 106 is approximately the same width as the thickness of the portable computing device 108 so that the sides of the portable computing device 108 can be disposed therein. Part of each grooved portion 606 extends over the rear face of the portable computing device 108 so it is held securely to the portable computing device 108 in the vertical direction (i.e., in the direction perpendicular to the plane defined by the front face of the portable computing device 108).

Also like the grooved portions 206A-206D in the curved lips 204A-204D of the holder base 102, each grooved portion 606 in the curved lips 604 of the cover 106 preferably has a width slightly less than the thickness of the portable computing device 108 so as to provide an interference fit between the curved lips 604 and the sides of the portable computing device 108. Accordingly, the cover 106 is preferably made from a somewhat flexible material so the curved lips 604 can be manipulated (e.g., bent, folded, deflected, etc.) around the portable computing device 108 to allow installation of the cover 106 on the portable computing device 108. That material, however, is preferably more rigid than the holder base 102 and grip flange 104, such as an ABS thermoplastic material, as to provide better protective qualities. And when that material is solid and opaque in the region of user interface, the cover 106 will need to be removed for a user to interact with the user interface of the portable computing device 108. In the alternative, the cover 108 can be modified to include a transparent material in the region of user interface that is more flexible than the remaining portions of the cover and/or that is electrically conductive so the user can interact with the user interface of the portable computing device 108 with the cover 106 installed thereon.

In addition to the components described above, the portable computer holder 100 of the present invention may include various other components to facilitate holding a portable computing device 108 in different manners. For example, the grip flange 104 may be removably attached to the holder base 102 so it can be replaced with various other attachment mechanisms, such as a ¼″-20 thread receptacle for mounting to a standard tripod. Or the attachment mechanism 214 on the holder base 102 can be configured so that it can be directly mounted to another device when the grip flange 104 is removed, such as by forming that attachment mechanism with a ¼″-20 thread receptacle for mounting to a standard tripod. Or other attachment mechanisms can be formed on or attached to the grip flange 104 so the grip flange 104 does not need to be removed, thereby reducing the number of parts of which a user needs to keep track.

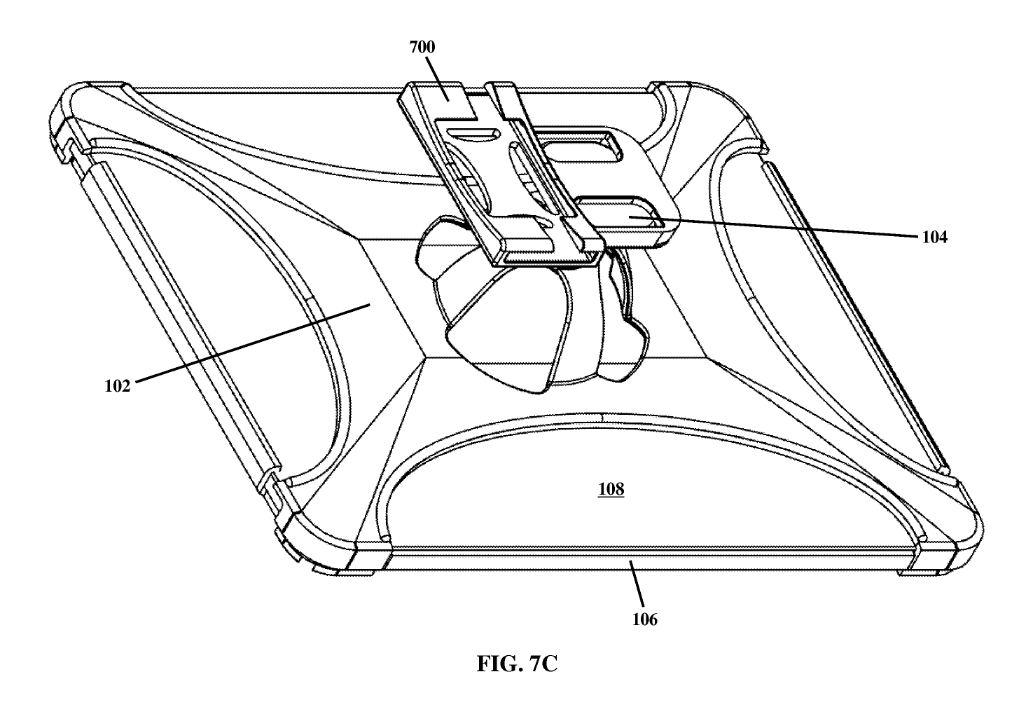

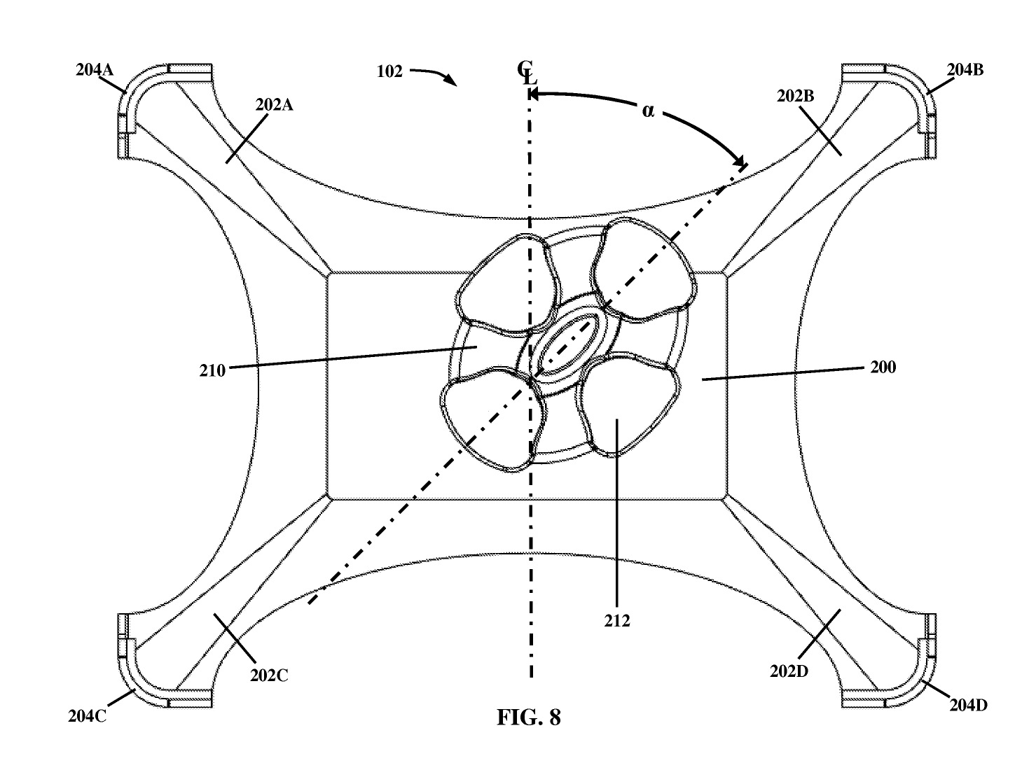

As FIGS. 7A-7C illustrate, a belt clip 700 can be attached directly to the grip flange 104 so a user can attach the portable computer holder to his or her belt. The belt clip 700 includes a rectangular upper portion 702 configured to attach to the user's belt and a rectangular lower portion 704 configured to attach to the grip flange 104. The upper portion 702 includes a groove 706 formed in a rear side thereof that is dimensioned to receive the user's belt therein. And the lower portion 704 includes a groove 708 formed in a front side thereof that is dimensioned to receive the grip base 300 of grip flange 104 therein. The groove 706 of the upper portion 702 is disposed on the opposite side of the belt clip 700 from the groove 708 of the lower portion 704 such that the portable computer holder 100 and, therefore, the front face of the portable computing device 108, will face away from the user when attached to the user's belt.

The upper portion 702 and lower portion 704 of the belt clip 700 include a plurality of openings 710 extending therethrough to reduce the weight and enhance the aesthetics of the belt clip. The lower portion 704 of the belt clip 700 further includes locking features (not shown) for keeping the grip flange 104 attached to the belt clip. Any suitable locking features can be used to provide that functionality. Other mechanisms for attaching the portable computer holder 100 to a user, such as a lanyard, may also be attached to the grip flange 104 or other part of the portable computer holder 100 in a similar manner.

Although certain presently preferred embodiments of the disclosed invention have been specifically described herein, it will be apparent to those skilled in the art to which the invention pertains that variations and modifications of the various embodiments shown and described herein may be made without departing from the spirit and scope of the invention. For example, the domed structure 210 may be offset from the centerline of the holder base 102, as illustrated in FIG. 8, so that more of a user's forearm can be used to support the weight of the portable computer holder 100 and portable computing device 108. Accordingly, it is intended that the invention be limited only to the extent required by the appended claims and the applicable rules of law.

What is claimed is:

1. A portable computer holder comprising:
a holder base with a front face and a rear face opposite the front face, the holder base being configured to hold a portable computing device at its front face by engaging distal edges of the portable computing device;
a dome-shaped grip extending from the rear face of the holder base, the dome-shaped grip having at least one opening for receiving a user's finger; and
a flange extending from the dome-shaped grip for supporting the holder base at an angle on a flat surface.

2. The portable computer holder of claim 1, wherein the holder base includes:
a central portion configured to mount flush with a rear face of the portable computing device;
a plurality of arms extending from the central portion at different angles, the plurality of arms also being configured to mount flush with the rear face of the portable computing device; and
a curved lip at a distal end of each of the plurality of arms, each curved having a grooved portion configured to hold a distal edge of the portable computing device therein.

3. The portable computer holder of claim 2, further comprising one or more feet extending from each curved lip a distance beyond a front face of the portable computing device.

4. The portable computer holder of claim 2, wherein the dome-shaped grip is elliptical in cross section and is disposed on the central portion of the holder base.

5. The portable computer holder of claim 4, wherein the dome-shaped grip is disposed at an angle with respect to an axis of symmetry of the holder base.

6. The portable computer holder of claim 5, wherein the at least one opening is in line with the angle.

7. The portable computer holder of claim 6, wherein the dome-shaped grip includes four openings in an array with each opening being separated from each other opening by ninety degrees.

8. The portable computer holder of claim 2, wherein the flange includes a flat base portion formed substantially parallel to the central portion of the holder base.

9. The portable computer holder of claim 8, wherein the flat base portion includes one or more flat peripheral edge.

10. The portable computer holder of claim 8, wherein the flat base portion includes an attachment mechanism for attaching the portable computer holder to at least one of a tripod, a user's belt, and a lanyard.

11. The portable computer holder of claim 2, further comprising a cover configured to cover a front face of the portable computing device, the cover having a main body that is substantially the same shape as the front face of the portable computing device except for a cutout where each curved lip holds a distal edge of the portable computing device.

12. The portable computer holder of claim 2, wherein at least the central portion and the plurality of arms are formed of a flexible material so they conform to the shape of a rear face of the portable computing device.

13. The portable computer holder of claim 1, wherein the holder base, dome-shaped grip, and flange are integrally formed from a single piece of material.

14. The portable computer holder of claim 1, wherein the dome-shaped grip is offset from a centerline of the holder base so that more of a user's forearm will support the portable computer holder.

15. A method for holding a portable computing device, the method comprising:
forming a holder base with a front face and a rear face opposite the front face, the holder base being configured to hold a portable computing device at its front face by engaging distal edges of the portable computing device;
forming a dome-shaped grip extending from the rear face of the holder base, the dome shaped grip having at least one opening for receiving a user's finger; and
forming a flange extending from the dome-shaped grip for supporting the holder base at an angle on a flat surface.

16. The portable computer holder of claim 15, wherein the step of forming the holder base includes:
forming a central portion configured to mount flush with a rear face of the portable computing device;
forming a plurality of arms extending from the central portion at different angles, the plurality of arms also being configured to mount flush with the rear face of the portable computing device; and
forming a curved lip at a distal end of each of the plurality of arms, each curved lip being formed with a grooved portion configured to hold a distal edge of the portable computing device therein.

17. The portable computer holder of claim 16, further comprising the step of forming one or more feet extending from each curved lip a distance beyond a front face of the portable computing device.

18. The portable computer holder of claim 16, wherein the step of forming the dome-shaped grip includes forming the dome-shaped grip with an elliptical cross section on the central portion of the holder base.

19. The portable computer holder of claim 18, wherein the dome-shaped grip is disposed at an angle with respect to an axis of symmetry of the holder base.

20. The portable computer holder of claim 19, wherein the at least one opening is in line with the angle.

21. The portable computer holder of claim 20, wherein the dome-shaped grip includes four openings in an array with each opening being separated from each other opening by ninety degrees.

22. The portable computer holder of claim 16, wherein the step of forming the flange includes forming the flange with a flat base portion substantially parallel to the central portion of the holder base.

23. The portable computer holder of claim 22, wherein the flat base portion includes one or more flat peripheral edge.

24. The portable computer holder of claim 22, wherein the flat base portion includes an attachment mechanism for attaching the portable computer holder to at least one of a tripod, a user's belt, and a lanyard.

25. The portable computer holder of claim 16, further comprising the step of forming a cover configured to cover a front face of the portable computing device, the cover having a main body that is substantially the same shape as the front face of the portable computing device except for a cutout where each curved lip holds a distal edge of the portable computing device.

26. The portable computer holder of claim 16, wherein at least the central portion and the plurality of arms are formed of a flexible material so they conform to the shape of a rear face of the portable computing device.

27. The portable computer holder of claim 15, wherein the holder base, dome-shaped grip, and flange are integrally formed from a single piece of material.

28. The portable computer holder of claim 15, wherein the step of forming the dome-shaped grip includes forming the dome-shaped grip offset from a centerline of the holder base so that more of a user's forearm will support the portable computer holder.
